(19) United States
(12) Patent Application Publication
(10) Pub. No.: US 2026/0100205 A1
(43) Pub. Date: Apr. 9, 2026

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventor: Hyunmook Choi, Suwon-si (KR)

(21) Appl. No.: 19/321,455

(22) Filed: Sep. 8, 2025

(30) Foreign Application Priority Data
Oct. 7, 2024 (KR) 10-2024-0135956

(51) Int. Cl. G11C 5/06; H01L 23/00; H01L 25/18; H10B 41/27; H10B 41/35; H10B 41/41; H10B 43/27; H10B 43/35; H10B 43/40; H10B 80/00; H10D 80/30

(52) U.S. Cl. CPC G11C 5/06; H10B 41/27; H10B 41/35; H10B 41/41; H10B 43/27; H10B 43/35; H10B 43/40; H10B 80/00; H10D 80/30; H10W 90/00; H10W 90/20; H10W 90/732; H10W 90/734; H10W 90/792

(57) ABSTRACT

A semiconductor device includes: a first substrate structure including a substrate, a first circuit element and a second circuit element in the substrate; and a second substrate structure on the first substrate structure, and including a plate layer, gate electrodes stacked, and channel structures extending into the gate electrodes, and the substrate includes a first semiconductor region extending into the substrate from the upper surface thereof and a second semiconductor region extending into the substrate from a lower surface thereof, the first circuit element includes a first gate electrode layer on a side surface of the first semiconductor region, the second circuit element includes a second gate electrode layer on a side surface of the second semiconductor region, and a first portion of an upper surface of the second semiconductor region is in contact with the first semiconductor region.

### CROSS-REFERENCE TO RELATED APPLICATION(S)

This application claims benefit of priority under 35 U.S.C. § 119 to Korean Patent Application No. 10-2024-0135956 filed on Oct. 7, 2024, in the Korean Intellectual Property Office, the disclosure of which is incorporated herein by reference in its entirety.

### BACKGROUND

In a data storage system requiring data storage, a semiconductor device capable of storing a large amount of data may be desirable. Accordingly, a method of increasing the data storage capacity of a semiconductor device has been researched. For example, as one of the methods of increasing the data storage capacity of a semiconductor device, a semiconductor device including memory cells arranged three-dimensionally instead of memory cells arranged two-dimensionally has been proposed. Additionally, a method of reducing an area of circuit elements driving memory cells has been researched in order to increase the integration of a semiconductor device.

### SUMMARY

An aspect of the present disclosure is to provide a semiconductor device having improved integration.

An aspect of the present disclosure is to provide a data storage system including a semiconductor device having improved integration.

A semiconductor device according to example implementations may include: a first substrate structure including a substrate, a first circuit element and a second circuit element sequentially arranged in the substrate in a first direction, perpendicular to an upper surface of the substrate, a first interconnection structure on the substrate, and first bonding pads on the first interconnection structure; and a second substrate structure on the first substrate structure, and including a plate layer, gate electrodes spaced apart from each other and stacked in the first direction, below the plate layer, channel structures penetrating through the gate electrodes and extending in the first direction, a second interconnection structure below the gate electrodes, and second bonding pads below the second interconnection structure and connected to the first bonding pads, and the substrate may include a first semiconductor region extending from the upper surface of the substrate into the substrate in the first direction and a second semiconductor region extending from a lower surface of the substrate into the substrate in the first direction and contacting the first semiconductor region, the first circuit element may include a first gate dielectric layer on a side surface of the first semiconductor region, a first gate electrode layer on the first gate dielectric layer, and first source/drain regions respectively disposed in an upper portion and a lower portion of the first semiconductor region, the second circuit element may include a second gate dielectric layer on a side surface of the second semiconductor region, a second gate electrode layer on the second gate dielectric layer, and second source/drain regions respectively disposed in an upper portion and a lower portion of the second semiconductor region, and in a second direction, perpendicular to the first direction, the first semiconductor region may have a first width, and the second semiconductor region has a second width greater than the first width.

A semiconductor device according to example implementations may include: a first substrate structure including a substrate, a first circuit element and a second circuit element sequentially arranged in the substrate in a first direction, perpendicular to an upper surface of the substrate, and an element isolation layer in the substrate; and a second substrate structure on the first substrate structure, and including a plate layer, gate electrodes spaced apart from each other and stacked in the first direction on one surface of the plate layer, and channel structures penetrating through the gate electrodes and extending in the first direction, and the substrate may include a first semiconductor region extending into the substrate of the substrate from the upper surface in the first direction and a second semiconductor region extending into the substrate from a lower surface of the substrate in the first direction, the first circuit element may include a first gate electrode layer on a side surface of the first semiconductor region, and first source/drain regions respectively disposed in an upper portion and a lower portion of the first semiconductor region, the second circuit element may include a second gate electrode layer on a side surface of the second semiconductor region, and second source/drain regions respectively disposed in an upper portion and a lower portion of the second semiconductor region, and a first portion of an upper surface of the second semiconductor region may be in contact with the first semiconductor region, and a second portion of the upper surface of the second semiconductor region is in contact with the element isolation layer.

A data storage system according to example implementations may include: a semiconductor storage device including a first substrate structure including a substrate, a first circuit element, and a second circuit element, a second substrate structure including gate electrodes, and an input/output pad electrically connected to the first and second circuit elements; and a controller electrically connected to the semiconductor storage device through the input/output pad and configured to control the semiconductor storage device, and the first circuit element and the second circuit element may be stacked in the substrate in a first direction, perpendicular to an upper surface of the substrate, and the first substrate structure may further include: a peripheral region insulating layer on the upper surface of the substrate; a backside insulating layer on a lower surface of the substrate; front contacts electrically connected to the first circuit element by penetrating through the peripheral region insulating layer; backside contacts electrically connected to the second circuit element by penetrating through the backside insulating layer; and a common contact electrically connected to the first circuit element and the second circuit element by penetrating through the peripheral region insulating layer.

A semiconductor device having improved integration and a data storage system including the same may be provided by including circuit elements having a vertical transport field effect transistor (VTFET) structure.

Advantages and effects of the present disclosure are not limited to the foregoing content and may be more easily understood in the process of describing a specific example implementation of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view of a semiconductor device according to example implementations;

FIG. 2 is a schematic plan view of a semiconductor device according to example implementations;

FIGS. 3A and 3B are partially enlarged views of a semiconductor device according to example implementations;

FIGS. 4A and 4B are partially enlarged views of a semiconductor device according to example implementations;

FIGS. 5A and 5B are partially enlarged views of a semiconductor device according to example implementations;

FIG. 6 is a schematic cross-sectional view of a semiconductor device according to example implementations;

FIGS. 7A to 7M are schematic cross-sectional views illustrating a method of manufacturing a semiconductor device according to example implementations;

FIG. 8 is a schematic view of a data storage system including a semiconductor device according to example implementations;

FIG. 9 is a perspective view schematically illustrating a data storage system including a semiconductor device according to example implementations; and

FIG. 10 is a schematic cross-sectional view of a semiconductor package according to example implementations.

### DETAILED DESCRIPTION

Hereinafter, example implementations of the present disclosure will be described with reference to the accompanying drawings. Hereinafter, it may be understood that the expressions such as “on,” “above,” “upper,” “below”, “beneath,” “lower,” and “side surface,” are indicated based on drawings, except that they are indicated by drawings and referred to separately.

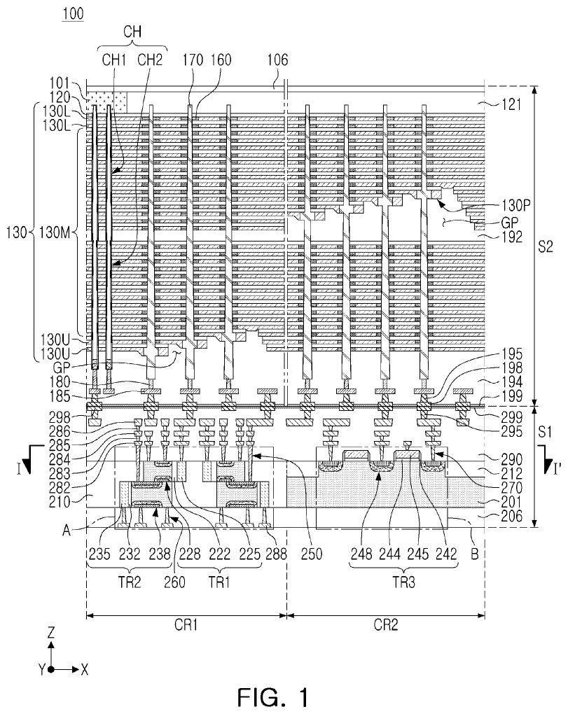

FIG. 1 is a schematic cross-sectional view of a semiconductor device according to example implementations.

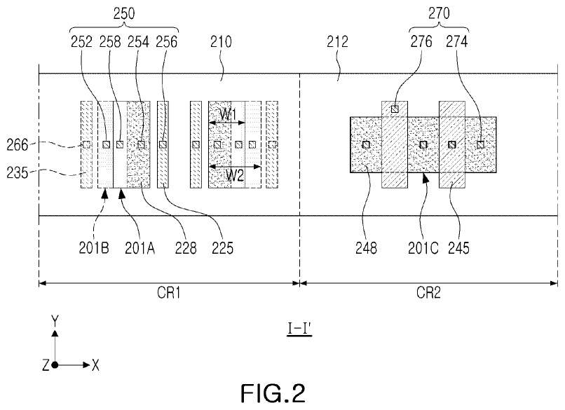

FIG. 2 is a schematic plan view of a semiconductor device according to example implementations. FIG. 2 illustrates a portion of a plane along line I-I′ of FIG. 1.

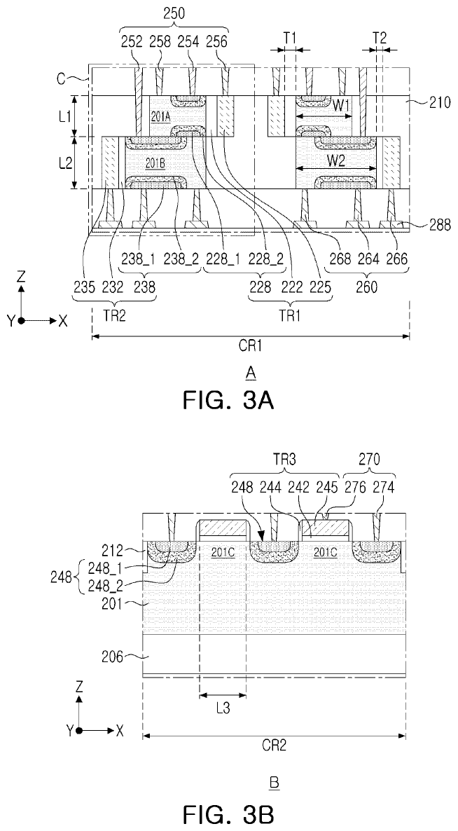

FIG. 3A and FIG. 3B are partially enlarged views of a semiconductor device according to example implementations. FIG. 3A is an enlarged view of region ‘A’ of FIG. 1, and FIG. 3B is an enlarged view of region ‘B’ of FIG. 1.

Referring to FIGS. 1 to 3B, a semiconductor device 100 includes first and second substrate structures S1 and S2 bonded to each other up and down. The first substrate structure S1 may include a peripheral circuit region, and the second substrate structure S2 may include a memory cell region.

The first substrate structure S1 may include a first circuit region CR1 and a second circuit region CR2. The first substrate structure S1 may include a substrate 201, first and second element isolation layers 210 and 212 in the substrate 201, first and second circuit elements TR1 and TR2 disposed in the substrate 201 in the first circuit region CR1, third circuit elements TR3 disposed on the substrate 201 in the second circuit region CR2, a peripheral region insulating layer 290 on an upper surface of the substrate 201, a backside insulating layer 206 on a lower surface of the substrate 201, first and second circuit contact plugs 283 and 285 and first to third circuit interconnection lines 282, 284 and 286 on the substrate 201, backside interconnection lines 288 below the substrate 201, first bonding vias 295, first bonding pads 298, and a first bonding insulating layer 299. The first substrate structure S1 may further include first front contacts 250 and backside contacts 260 disposed in the first circuit region CR1, and second front contacts 270 disposed in the second circuit region CR2.

The substrate 201 may have an upper surface extending in an X-direction and a Y-direction. First and second element isolation layers 210 and 212 may be formed in the substrate 201 to define first to third semiconductor regions 201A, 201B and 201C. In the first circuit region CR1, the first and second semiconductor regions 201A and 201B may be defined by the first element isolation layer 210, and in the second circuit region CR2, the third semiconductor region 201C may be defined by the second element isolation layer 212. The first to third semiconductor regions 201A, 201B and 201C may also be referred to as first to third active regions.

First to third source/drain regions 228, 238 and 248 including impurities may be disposed in some of the first to third semiconductor regions 201A, 201B and 201C. The substrate 201 may include a semiconductor material, such as a group IV semiconductor, a group III-V compound semiconductor, or a group II-VI compound semiconductor. For example, the substrate 201 may be provided as a single crystal bulk wafer and may include impurities. Each of the source/drain regions can be used as either a source terminal or a drain terminal. For example, turning briefly to FIG. 3A, the first semiconductor region 201A has two first source/drain regions 228: a first upper region in an upper portion of the first semiconductor region 201A and a first lower region in a lower portion of the first semiconductor region 201A. In an implementation, the first upper region 228 in the upper portion of the first semiconductor region 201A is a source terminal, while the first lower region 228 in the lower portion of the first semiconductor region 201A is a drain terminal. In another implementation, the first upper region 228 in the upper portion of the first semiconductor region 201A is a drain terminal, while the first lower region 228 in the lower portion of the first semiconductor region 201A is a source terminal. Similarly, the second semiconductor region 201B has two second source/drain regions 238: a second upper region in an upper portion of the second semiconductor region 201B and a second lower region in a lower portion of the second semiconductor region 201B. In an implementation, the second upper region 238 in the upper portion of the second semiconductor region 201B is a source terminal, while the second lower region 238 in the lower portion of the second semiconductor region 201B is a drain terminal. In another implementation, the second upper region 238 in the upper portion of the second semiconductor region 201B is a drain terminal, while the second lower region 238 in the lower portion of the second semiconductor region 201B is a source terminal. In some implementations, the first lower region 228 in the lower portion of the first semiconductor region 201A is a source terminal, and the second upper region 238 in the upper portion of the second semiconductor region 201B is a source terminal.

The first and second element isolation layers 210 and 212 may define the first to third semiconductor regions 201A, 201B and 201C in the substrate 201. The first element isolation layer 210 may be disposed in the first circuit region CR1 and may penetrate through the substrate 201. The second element isolation layer 212 may be disposed in the second circuit region CR2, and may extend from the upper surface of the substrate 201 into the substrate 201 by a predetermined depth without penetrating through the substrate 201. The first element isolation layer 210 may include an upper region extending from the upper surface of the substrate 201 and a lower region extending from the lower surface of the substrate 201, and the upper region and the lower region may be in contact with or connected to each other.

Each of the upper region and the lower region of the first element isolation layer 210, and the second element isolation layer 212 may be formed in, for example, a shallow trench isolation (STI) process. In example implementations, the arrangement form and depth of the first and second element isolation layers 210 and 212 may be variously changed. The first and second element isolation layers 210 and 212 may be formed of an insulating material, for example, an oxide, a nitride, or combinations thereof.

The first and second circuit elements TR1 and TR2 may be disposed in the substrate 201 in the first circuit region CR1, and may include a vertical transport field effect transistor (VTFET) in which a channel direction of each transistor is a direction, perpendicular to the upper surface of the substrate 201, for example, a Z-direction. In the first and second circuit elements TR1 and TR2, a channel of the transistor may be formed between the first and second source/drain regions 228 and 238 in the substrate 201, respectively. The first and second circuit elements TR1 and TR2 may be stacked in the Z-direction so as to penetrate through the substrate 201 together. The first circuit element TR1 and the second circuit element TR2 may have different threshold voltages and different operating voltages. For example, the first circuit element TR1 may include a high-voltage transistor having a first threshold voltage and a first operating voltage, and the second circuit element TR2 may include a low-voltage transistor having a second threshold voltage lower than the first threshold voltage and a second operating voltage lower than the first operating voltage.

The first circuit element TR1 may include a first gate dielectric layer 222, a first gate electrode layer 225, and first source/drain regions 228. The first gate dielectric layer 222 and the first gate electrode layer 225 may be disposed to extend in the Z-direction from the upper surface of the substrate 201 by penetrating through a portion of the substrate 201. The first gate dielectric layer 222 may be disposed on a first side surface of the first semiconductor region 201A, and the first gate electrode layer 225 may be disposed on a side surface of the first gate dielectric layer 222. In the first semiconductor region 201A, the first side surface may correspond to a right surface in FIG. 3A, and a second side surface may correspond to a left surface in FIG. 3A.

The first gate dielectric layer 222 and the first gate electrode layer 225 may have a shape of the alphabet ‘I’ or the number ‘1’ in a cross-sectional view as in FIG. 1. Upper surfaces of the first gate dielectric layer 222 and the first gate electrode layer 225 may be coplanar with the upper surface of the substrate 201. The first source/drain regions 228 may be disposed to extend from an upper surface and a lower surface of the first semiconductor region 201A into the first semiconductor region 201A, respectively. An upper surface of a first source/drain region 228 in an upper portion may be coplanar with the upper surface of the substrate 201 or the first semiconductor region 201A. A lower surface of the first source/drain region 228 in a lower portion may be coplanar with the lower surface of the first semiconductor region 201A, or may extend partially to an adjacent second semiconductor region 201B. One side surface of the first source/drain region 228, for example, the right surface, may be coplanar with the first side surface of the first semiconductor region 201A.

The second circuit element TR2 may include a second gate dielectric layer 232, a second gate electrode layer 235, and second source/drain regions 238. The second gate dielectric layer 232 and the second gate electrode layer 235 may be disposed to extend in the Z-direction from the lower surface of the substrate 201 by penetrating through a portion the substrate 201. The second gate dielectric layer 232 may be disposed on a second side surface of the second semiconductor region 201B, and the second gate electrode layer 235 may be disposed on a side surface of the second gate dielectric layer 232. In the second semiconductor region 201B, a first side surface may correspond to a right surface in FIG. 3A, and the second side surface may correspond to a left surface in FIG. 3A.

The second gate dielectric layer 232 and the second gate electrode layer 235 may have a shape of the alphabet ‘I’ or the number ‘1’ in the cross-sectional view as in FIG. 1. Lower surfaces of the second gate dielectric layer 232 and the second gate electrode layer 235 may be coplanar with the lower surface of the substrate 201. The second source/drain regions 238 may be disposed to extend from an upper surface and a lower surface of the second semiconductor region 201B into the second semiconductor region 201B, respectively. An upper surface of a second source/drain region 238 in the upper portion may be coplanar with the upper surface of the second semiconductor region 201B, or may extend to the adjacent first semiconductor region 201A. A lower surface of second source/drain region 238 in the lower portion may be coplanar with the lower surface of the substrate 201 or the second semiconductor region 201B. One side surface of the second semiconductor region 201B, for example, the left surface, may be coplanar with the second side surface of the second semiconductor region 201B.

In the X-direction, a first thickness T1 (also called width in the present disclosure) of the first gate dielectric layer 222 may be greater than a second thickness T2 of the second gate dielectric layer 232. For example, the first thickness T1 may be in a range of about 20 nm to about 60 nm, and the second thickness T2 may be in a range of about 1 nm to about 5 nm, but the present disclosure is not limited thereto. In the Z-direction, a first length L1 of the first gate electrode layer 225 may be less than a second length L2 of the second gate electrode layer 235. For example, the first length L1 may be in a range of about 1 μm to about 3 μm, and the second length L2 may be in a range of about 5 μm to about 20 μm, for example, a range of about 8 μm to about 12 μm, but the present disclosure is not limited thereto.

In the substrate 201, the first and second semiconductor regions 201A and 201B may be regions connected to each other in the Z-direction. The lower surface of the first semiconductor region 201A may be in contact with the upper surface of the second semiconductor region 201B. In a horizontal direction, for example, the X-direction, a second width W2 of the second semiconductor region 201B may be greater than a first width W1 of the first semiconductor region 201A. Accordingly, a first portion of the upper surface of the second semiconductor region 201B may be covered with the first semiconductor region 201A, and the remaining portion thereof, that is, a second portion may be exposed from the first semiconductor region 201A and may be covered with the first element isolation layer 210.

A first source/drain region 228 disposed in a lower portion of the first semiconductor region 201A, among the first source/drain regions 228, may be electrically connected to a second source/drain region 238 disposed in an upper portion of the second semiconductor region 201B, among the second source/drain regions 238. A portion of a lower surface of the first source/drain region 228 may be in contact with a portion of an upper surface of the second source/drain region 238.

The third circuit elements TR3 may be disposed on the upper surface of the substrate 201 in the second circuit region CR2 and may include a planar transistor. A channel direction of each of the third circuit elements TR3 may be a direction, parallel to the upper surface of the substrate 201, for example, the X-direction. A channel direction of the third circuit elements TR3 may be perpendicular to channel directions of the first and second circuit elements TR1 and TR2. In the third circuit element TR3, the channel may be formed in the third semiconductor region 201C between the third source/drain regions 248. The third circuit elements TR3 may be a high-voltage transistor to which the same or different voltage as that of the first circuit elements TR1 is applied, or a low-voltage transistor to which the same or different voltage as that of the second circuit elements TR2 is applied.

The third circuit element TR3 may include a third gate dielectric layer 242, a third gate electrode layer 245, third source/drain regions 248, and gate spacers 244. The third gate dielectric layer 242 may be disposed on the third semiconductor region 201C, and the third gate electrode layer 245 may be disposed on the third gate dielectric layer 242. A third length L3 of the third gate electrode layer 245 in the X-direction may be less than at least one of the first length L1 or the second length L2. The gate spacers 244 may be disposed on side surfaces of the third gate dielectric layer 242 and the third gate electrode layer 245. The third source/drain regions 248 may be disposed in the substrate 201 on both sides of the third gate dielectric layer 242 and the third gate electrode layer 245.

Each of the first to third gate dielectric layers 222, 232 and 242 may include an oxide, a nitride, or a high-κ material. The first to third gate dielectric layers 222, 232 and 242 may include the same material or may include different materials. The first to third gate electrode layers 225, 235 and 245 may include a conductive material, for example, a semiconductor material such as doped polysilicon, and/or a metallic material such as aluminum (Al), tungsten (W), or molybdenum (Mo). The first to third gate electrode layers 225, 235 and 245 may include the same material or may include different materials. In some example implementations, conductive layers of each of the first to third gate electrode layers 225, 235 and 245 may be plural.

The first to third source/drain regions 228, 238 and 248 may be doped regions in the substrate 201. The first to third source/drain regions 228, 238 and 248 may include first impurity regions 228_1, 238_1 and 248_1 and second impurity regions 228_2, 238_2 and 248_2 having different doping concentrations, respectively. For example, in each of the first to third source/drain regions 228, 238 and 248, an impurity concentration of the first impurity region 228_1, 238_1 and 248_1 that are relatively shallow may be higher than an impurity concentration of the second impurity region 228_2, 238_2 and 248_2. The first source/drain regions 228 may have different doping concentrations from the second source/drain regions 238, and for example, an impurity concentration of the first impurity region 228_1 of the first source/drain region 228 may be greater than an impurity concentration of the first impurity region 238_1 of the second source/drain region 238. However, in example implementations, the number and shape of the impurity regions of each of the first to third source/drain regions 228, 238 and 248 may be variously changed.

The gate spacers 244 may be formed of at least one of an oxide, a nitride, or an oxynitride, and may be formed of, for example, a low-κ film.

In the semiconductor device 100, since the first and second circuit elements TR1 and TR2 are disposed vertically in the substrate 201 so as to penetrate through the substrate 201, the integration thereof may be improved as compared to a case in which the first and second circuit elements TR1 and TR2 are disposed as planar transistors together with the third circuit elements TR3. The first and second circuit elements TR1 and TR2 may include, for example, elements having the longest channel length among the transistors disposed in the first substrate structure S1. For example, when some of the first circuit elements TR1 and some of the third circuit elements TR3 are driven by the same operating voltage, the first circuit elements TR1 may be selected as elements having a longer channel length than the third circuit elements TR3, or elements in which the first length L1 of the first gate electrode layer 225 is longer than the third length L3 of the third gate electrode layer 245.

The peripheral region insulating layer 290 may be disposed on the first to third circuit elements TR1, TR2 and TR3 on the upper surface of the substrate 201. The backside insulating layer 206 may be disposed on the lower surface of the substrate 201. Each of the peripheral region insulating layer 290 and the backside insulating layer 206 may include a plurality of insulating layers formed in different process operations. Each of the peripheral region insulating layer 290 and the backside insulating layer 206 may be formed of an insulating material, and may include, for example, at least one of an oxide, a nitride, or an oxynitride.

The first front contacts 250 may penetrate through the peripheral region insulating layer 290 in the first circuit region CR1 and may be electrically connected to at least the first circuit elements TR1. The first front contacts 250 may include a first source/drain contact 254 connected to the first source/drain region 228 extending from an upper surface of the first semiconductor region 201A, a first gate contact 256 connected to the first gate electrode layer 225, and a first body contact 258 connected to the first semiconductor region 201A. The first source/drain contact 254 may be connected to the first impurity region 228_1, but the present disclosure is not limited thereto.

The first front contacts 250 may further include a common source/drain contact 252 connected to the second source/drain region 238 disposed in the upper portion of the second semiconductor region 201B by extending into a portion of the first element isolation layer 210. The common source/drain contact 252 may be connected to the first impurity region 238_1, but the present disclosure is not limited thereto. The common source/drain contact 252 may be electrically connected to the second source/drain region 238, and may also be electrically connected to the first source/drain region 228 disposed in a lower portion of the first semiconductor region 201A through the second source/drain region 238. In some example implementations, the first body contact 258 may be omitted.

The backside contacts 260 may be electrically connected to the second circuit elements TR2 by penetrating through the backside insulating layer 206 in the first circuit region CR1. The backside contacts 260 may include a backside source/drain contact 264 connected to the second source/drain region 238 extending from the lower surface of the second semiconductor region 201B, a backside gate contact 266 connected to the second gate electrode layer 235, and a backside body contact 268 connected to the second semiconductor region 201B. The backside source/drain contact 264 may be connected to the first impurity region 238_1, but the present disclosure is not limited thereto. In some example implementations, the backside body contact 268 may be omitted.

Each of the backside contacts 260 may have an inclined side surface so that a width of an upper surface thereof is less than a width of a lower surface thereof. An inclination of side surfaces of the backside contacts 260 may be opposite to an inclination of side surfaces of the first and second front contacts 250 and 270 based on substrate 201.

The second front contacts 270 may be electrically connected to the third circuit elements TR3 by penetrating through the peripheral region insulating layer 290 in the second circuit region CR2. The second front contacts 270 may include third source/drain contacts 274 connected to the third source/drain regions 248 and a third gate contact 276 connected to the third gate electrode layer 245. The third source/drain contacts 274 may be connected to the first impurity regions 248_1, but the present disclosure is not limited thereto.

Each of the first and second front contacts 250 and 270 may have an inclined side surface so that a width of an upper surface thereof is greater than a width of a lower surface thereof. Upper ends of the first front contacts 250 and upper ends of the second front contacts 270 may be disposed on substantially the same level, but the present disclosure is not limited thereto.

In some example implementations, at least one of the first and second front contacts 250 and 270 and the backside contacts 260 may be disposed to recess the substrate 201 or the gate electrodes 256, 266 and 276 by a predetermined depth. In some example implementations, at least portions of the first and second front contacts 250 and 270 and the backside contacts 260 may be disposed to recess the substrate 201 by different depths.

Each of the first and second front contacts 250 and 270 and the backside contacts 260 may include a conductive material, for example, at least one of a semiconductor material, a metal-semiconductor compound, or a metallic material such as tungsten (W), cobalt (Co), molybdenum (Mo), copper (Cu), ruthenium (Ru), or aluminum (Al), and may further include a diffusion barrier layer.

The first and second circuit contact plugs 283 and 285 and the first to third circuit interconnection lines 282, 284 and 286 may be included in a portion of the first interconnection structure together with the first and second front contacts 250 and 270 and the backside contacts 260, and may be disposed on the upper surface of the substrate 201. The first and second circuit contact plugs 283 and 285 and the first to third circuit interconnection lines 282, 284 and 286 may be electrically connected to the first and second front contacts 250 and 270.

The backside interconnection lines 288 included in a portion of the first interconnection structure may be disposed on the lower surface of the substrate 201, and may be connected to the backside contacts 260. At least some of the backside interconnection lines 288 may be included in a backside power delivery network (BSPDN), and may transmit power to at least some of the first and second circuit elements TR1 and TR2.

Each of the first and second circuit contact plugs 283 and 285 may have a cylindrical shape. Each of the first to third circuit interconnection lines 282, 284 and 286 and the backside interconnection lines 288 may have a line shape. The first and second circuit contact plugs 283 and 285, the first to third circuit interconnection lines 282, 284 and 286, and the backside interconnection lines 288 may include a conductive material, and may include, for example, tungsten (W), copper (Cu), aluminum (Al), or the like, and may further include a diffusion barrier layer, respectively. However, in example implementations, the number of layers of the first and second circuit contact plugs 283 and 285, the first to third circuit interconnection lines 282, 284 and 286, and the backside interconnection lines 288, and an arrangement form thereof may be variously changed.

The first bonding vias 295, the first bonding pads 298, and the first bonding insulating layer 299 may be included in a first bonding structure, and may be disposed on third circuit interconnection lines 268 in an uppermost portion. The first bonding vias 295 may have a cylindrical shape, and the first bonding pads 298 may have a line shape. Upper surfaces of the first bonding pads 298 and upper surfaces of the first bonding insulating layer 299 may form an upper surface of the first substrate structure S1. The first bonding vias 295 and the first bonding pads 298 may provide an electrical connection path between the first substrate structure S1 and the second substrate structure S2. In some example implementations, some of the first bonding pads 298 may be disposed merely for bonding without being connected to the third circuit interconnection line 268 in a lower portion. The first bonding vias 295 and the first bonding pads 298 may include a conductive material, for example, copper (Cu). The first bonding insulating layer 299 may be disposed around the first bonding pads 298. The first bonding insulating layer 299 may also function as a diffusion barrier layer of the first bonding pads 298 and may include, for example, at least one of SiN, SiON, SiCN, SiOC, SiOCN, or SiO.

The second substrate structure S2 may include a plate layer 101, gate electrodes 130 stacked on a lower surface of the plate layer 101, interlayer insulating layers 120 alternately stacked with the gate electrodes 130, channel structures CH penetrating through the gate electrodes 130, and cell contact plugs 170 connected to the gate electrodes 130 and extending vertically. The second substrate structure S2 may further include a substrate insulating layer 121, a passivation layer 106, contact insulating layers 160 surrounding the cell contact plugs 170, studs 180 on lower surfaces of the channel structures CH and the cell contact plugs 170, cell interconnection lines 185 on the studs 180, and first and second cell region insulating layers 192 and 194 covering the gate electrodes 130. The second substrate structure S2 may further include second bonding vias 195, second bonding pads 198, and a second bonding insulating layer 199 as a second bonding structure.

The plate layer 101 may have an upper surface extending in the X-direction and the Y-direction. The plate layer 101 may function as a common source line of the second substrate structure S2. The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer such as a polycrystalline silicon layer, or an epitaxial layer. In some example implementations, the plate layer 101 may include a plurality of vertically stacked conductive layers.

The gate electrodes 130 may be vertically spaced from each other and stacked on the lower surface of the plate layer 101 to form a stack structure together with the interlayer insulating layers 120. The stack structure may include upper and lower stack structures vertically stacked and surrounding first and second channel structures CH1 and CH2, respectively. However, according to example implementations, the stack structure may be formed as a single stack structure.

The gate electrodes 130 may include at least one lower gate electrode 130L included in a gate of a ground select transistor, memory gate electrodes 130M included in a plurality of memory cells, and upper gate electrodes 130U included in gates of string select transistors. Here, the lower gate electrode 130L and the upper gate electrodes 130U may be referred to as “lower” and “upper” based on a direction during a manufacturing process. The number of memory gate electrodes 130M of the memory cells may be determined depending on the capacity of the semiconductor device 100. According to an example implementation, the number of upper and lower gate electrodes 130U and 130L may be 1 to 4 or more, respectively, and the upper and lower gate electrodes 130U and 130L may have a structure identical to or different from the memory gate electrodes 130M. In example implementations, the gate electrodes 130 may further include a gate electrode 130 included in an erase transistor disposed below the upper gate electrodes 130U and/or on the lower gate electrode 130L and used for an erase operation using a gate induced drain leakage (GIDL) phenomenon. Additionally, some of the gate electrodes 130, for example, the memory gate electrodes 130M adjacent to the upper or lower gate electrodes 130U and 130L, may be dummy gate electrodes.

The gate electrodes 130 may extend by different lengths to form staircase-shaped step structures in a plurality of staircase regions GP. The gate electrodes 130 may have a form removed from a lower portion of one of the upper and lower stack structures of the gate electrodes 130 by a predetermined depth in the staircase regions GP. The staircase regions GP may be disposed so as not to overlap each other in the Z-direction. On the staircase region GP of the lower stack structure, at least some of the gate electrodes 130 included in the upper stack structure may extend horizontally. In example implementations, an arrangement form, an arrangement order, and a depth of the staircase regions GP may be variously changed.

By the step structure of the plurality of staircase regions GP, the gate electrodes 130 may have regions in which lower surfaces thereof are exposed from the interlayer insulating layers 120 and other gate electrodes 130 by allowing the upper gate electrode 130 to extend longer than the lower gate electrode 130, and the regions may be referred to as pad regions 130P. In each gate electrode 130, the pad region 130P may be a region including an end of the gate electrode 130 in the X-direction. The gate electrodes 130 may be respectively connected to the cell contact plugs 170 in the pad regions 130P. The gate electrodes 130 may include regions in which a thickness thereof is increased in the pad regions 130P.

The gate electrodes 130 may include a metallic material, for example, tungsten (W). According to an example implementation, the gate electrodes 130 may include polycrystalline silicon or a metal silicide material. In example implementations, the gate electrodes 130 may further include a diffusion barrier, and, for example, the diffusion barrier may include tungsten nitride (WN), tantalum nitride (TaN), titanium nitride (TiN), or combinations thereof.

The interlayer insulating layers 120 may be disposed between the gate electrodes 130. The interlayer insulating layers 120 may also be spaced apart from each other in a direction, perpendicular to the lower surface of the plate layer 101, similarly to the gate electrodes 130, and may extend in the Y-direction. The interlayer insulating layers 120 may include an insulating material such as silicon oxide or silicon nitride.

Each of the channel structures CH may be included in one memory cell string, and may be spaced apart from each other in rows and columns on the lower surface of the plate layer 101. The channel structures CH may be disposed to form a grid pattern on the plan view or may be disposed in a zigzag shape in one direction. The channel structures CH may have a pillar shape, and may have inclined side surfaces so that a width thereof becomes narrower as the channel structures CH approach the plate layer 101 depending on the aspect ratio.

Each of the channel structures CH may have a form in which the first and second channel structures CH1 and CH2 penetrating the upper and lower stack structures of the gate electrodes 130 are connected, and may have a bent portion due to a difference or a change in width in a connection region. However, according to example implementations, the number of channel structures stacked in the Z-direction may be variously changed.

Each of the channel structures CH may include a channel dielectric layer, a channel layer, and a channel-filled insulating layer sequentially disposed from the gate electrodes 130 in a channel hole, and may include a channel pad disposed in a lower end of the channel hole. The channel layer may include a semiconductor material such as polycrystalline silicon or single crystal silicon and may be physically and electrically connected to the plate layer 101 through the upper end. The channel dielectric layer may include a tunneling layer, a charge storage layer, and a blocking layer sequentially stacked from the channel layer.

The cell contact plugs 170 may electrically connect the gate electrodes 130 to the first interconnection structure in the first substrate structure S1. The cell contact plugs 170 may be physically and electrically connected to the gate electrodes 130 in each pad region 130P, thus applying an electrical signal to the gate electrodes 130. The cell contact plugs 170 may penetrate through the vertically stacked gate electrodes 130. Upper ends of the cell contact plugs 170 may extend into the substrate insulating layer 121. The cell contact plugs 170 may be electrically separated from the plate layer 101 by the substrate insulating layer 121. However, in some example implementations, the cell contact plugs 170 may have a form that does not penetrate through the gate electrodes 130.

The cell contact plugs 170 may have a form that extends horizontally in the pad regions 130P. The cell contact plugs 170 may be spaced apart from the gate electrodes 130 above and below the pad regions 130P by the contact insulating layers 160. The contact insulating layers 160 may surround a side surface of each of the cell contact plug 170 and may be spaced apart from each other in the Z-direction. The contact insulating layers 160 may be disposed on substantially the same level as the gate electrodes 130, respectively. The contact insulating layers 160 may include an insulating material, for example, silicon oxide, silicon nitride, or silicon oxynitride.

The cell contact plugs 170 may include a conductive material, for example, at least one of tungsten (W), copper (Cu), aluminum (Al), or alloys thereof. In some example implementations, the cell contact plugs 170 may include a barrier layer extending along a side surface and a bottom surface thereof, or may have an air gap therein.

The studs 180 and the cell interconnection lines 185 may be included in a second interconnection structure electrically connected to the memory cells of the second semiconductor structure S2. The studs 180 may be connected to the channel structures CH and the cell contact plugs 170, and may electrically connect the channel structures CH and the gate electrodes 130 to the cell interconnection lines 185. The studs 180 may have a plug shape, and the cell interconnection lines 185 may have a line shape. In example implementations, the number of plugs and interconnection lines included in the cell interconnection structure may be variously changed. The studs 180 and the cell interconnection lines 185 may include a metal, for example, tungsten (W), copper (Cu), or aluminum (Al).

The first and second cell region insulating layers 192 and 194 may be disposed to cover the lower and upper stack structures, respectively. The passivation layer 106 may be disposed on the upper surface of the plate layer 101, and may function as a layer protecting the semiconductor device 100. Each of the first and second cell region insulating layers 192 and 194 and the passivation layer 106 may include at least one of an insulating material, for example, silicon oxide, silicon nitride, or silicon carbide, and may be formed of a plurality of insulating layers according to example implementations.

The second bonding vias 195 of the second bonding structure may be disposed below the cell interconnection lines 185 and may be connected to the cell interconnection lines 185, and the second bonding pads 198 of the second bonding structure may be connected to the second bonding vias 195. The second bonding pads 198 may have a lower surface that forms a lower surface of the second substrate structure S2. The second bonding pads 198 may be bonded and connected to the first bonding pads 298 of the first substrate structure S1, and the second bonding insulating layer 199 may be bonded and connected to the first bonding insulating layer 299 of the first substrate structure S1. The second bonding vias 195 and the second bonding pads 198 may include a conductive material, for example, copper (Cu). The second bonding insulating layer 199 may include, for example, at least one of SiO, SiN, SiCN, SiOC, SiON, or SiOCN.

The first and second substrate structures S1 and S2 may be bonded to each other by bonding the first bonding pads 298 and the second bonding pads 198 and bonding the first bonding insulating layer 299 and the second bonding insulating layer 199. The bonding of the first bonding pads 298 and the second bonding pads 198 may be, for example, copper (Cu)-to-copper (Cu) bonding, and the bonding of the first bonding insulating layer 299 and the second bonding insulating layer 199 may be, for example, dielectric-to-dielectric bonding, such as SiCN-to-SiCN bonding. The first and second substrate structures S1 and S2 may be bonded to each other by hybrid bonding including copper (Cu)-to-copper (Cu) bonding and dielectric-to-dielectric bonding.

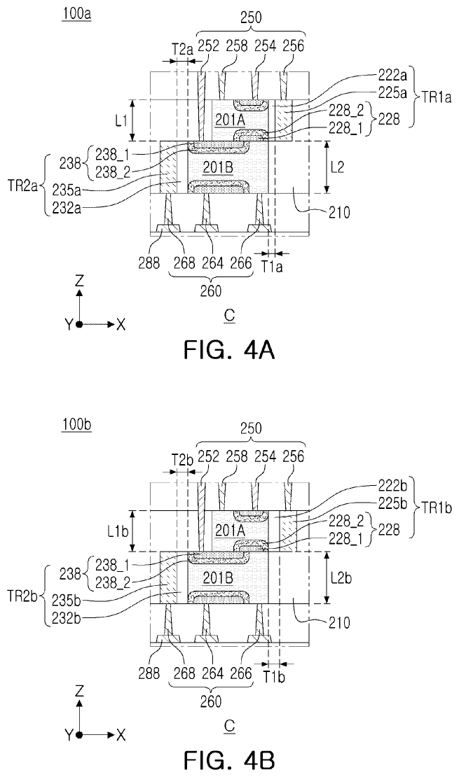

FIGS. 4A and 4B are schematic partially enlarged views of semiconductor devices according to example implementations. FIGS. 4A and 4B illustrate regions corresponding to region ‘C’ of FIG. 3A.

Referring to FIG. 4A, in a semiconductor device 100a, a first circuit element TR1a may include a low-voltage transistor, and a second circuit element TR2a may include a high-voltage transistor, unlike the implementations of FIGS. 1 to 3B. In the X-direction, a first thickness T1a of a first gate dielectric layer 222a may be less than a second thickness T2a of the second gate dielectric layer 232a. In this example implementation, in the Z-direction, a first length L1 of the first gate electrode layer 225a may be less than a second length L2 of the second gate electrode layer 235a, but the present disclosure is not limited thereto. In some example implementations, the first length L1 may be greater than the second length L2.

Referring to FIG. 4B, in a semiconductor device 100b, both the first and second circuit elements TR1b and TR2b may include high-voltage transistors, unlike the implementations of FIGS. 1 to 3B. In the X-direction, a first thickness T1b of the first gate dielectric layer 222b may be substantially equal to a second thickness T2b of a second gate dielectric layer 232b. In this example implementation, in the Z-direction, a first length L1b of a first gate electrode layer 225b may be equal to or different from a second length L2b of a second gate electrode layer 235b.

As illustrated in FIGS. 4A and 4B, in example implementations, the first and second circuit elements arranged in a parallel manner in the Z-direction in the substrate 201 may have the same operating voltage or different operating voltages, and an arrangement order of the low-voltage transistors and the high-voltage transistors in the Z-direction in the substrate 201 may also be variously changed.

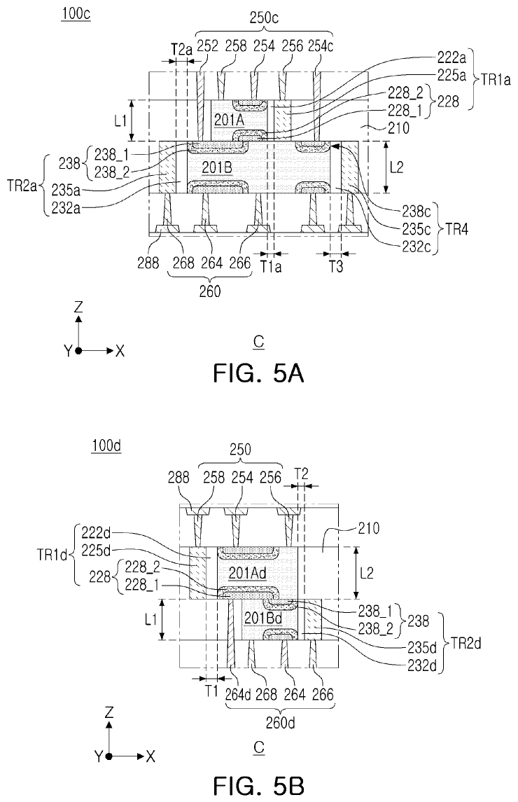

FIGS. 5A and 5B are schematic enlarged views of a semiconductor device according to example implementations. FIGS. 5A and 5B illustrate a region corresponding to region ‘C’ of FIG. 3A.

Referring to FIG. 5A, a semiconductor device 100c may further include a fourth circuit element TR4 disposed in a parallel manner in the X-direction with the second circuit element TR2a, unlike the example implementation of FIG. 4A. The fourth circuit element TR4 may share the second semiconductor region 201B with the second circuit element TR2a, and may include a high-voltage transistor, such as the second circuit element TR2a. However, in some example implementations, the low voltage transistors may be arranged in a parallel manner in the X-direction in a lower region of the substrate 201.

The fourth circuit element TR4 may include a second gate dielectric layer 232c, a second gate electrode layer 235c, and second source/drain regions 238c. In the X-direction, a third thickness T3 of the second gate dielectric layer 232c may be substantially the same as a second thickness T2a of the second gate dielectric layer 232a. First front contacts 250c may further include a second source/drain contact 254c partially penetrating through the first element isolation layer 210 from an upper surface thereof connected to the second source/drain region 238c in an upper portion.

Referring to FIG. 5B, in a semiconductor device 100d, a width of a first semiconductor region 201Ad in which a first circuit element TR1d is disposed may be greater than a width of a second semiconductor region 201Bd in which a second circuit element TR2d is arranged, unlike the example implementation of FIGS. 1 to 3B. Accordingly, a portion of a lower surface of the first semiconductor region 201Ad may be exposed from the second semiconductor region 201Bd. For example, the first and second circuit elements TR1d and TR2d may have a structure in which the first and second circuit elements TR1 and TR2 of FIG. 3 are inverted upside down.

Backside contacts 260d may further include a backside source/drain contact 264d partially penetrating through the first element isolation layer 210 from a lower surface thereof and connected to the first source/drain region 228 in a lower portion.

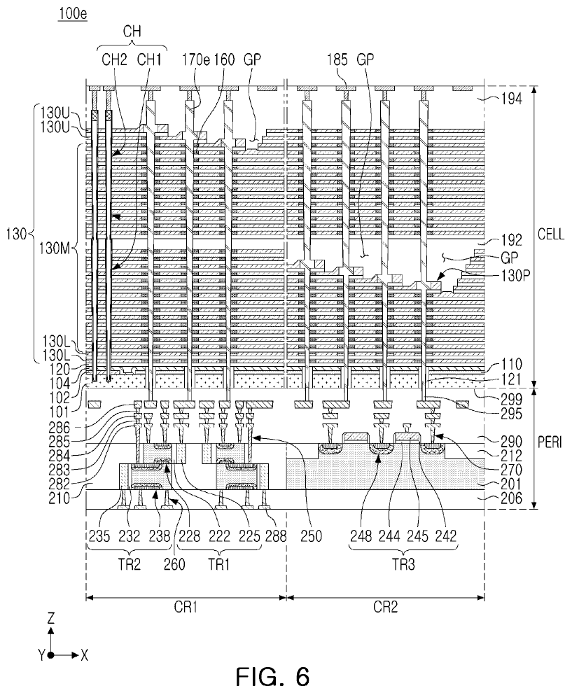

FIG. 6 is a schematic cross-sectional view of a semiconductor device according to example implementations.

Referring to FIG. 6, a semiconductor device 100e may include a peripheral circuit region PERI including a substrate 201 and a memory cell region CELL including a plate layer 101. The memory cell region CELL may be disposed on the peripheral circuit region PERI. In example implementations, conversely, the memory cell region CELL may be disposed below the peripheral circuit region PERI. In the claims, and the like, the peripheral circuit region PERI may be referred to as a first substrate structure, and the memory cell region CELL may be referred to as a second substrate structure.

The description of the first semiconductor structure S1 described above with reference to FIGS. 1 to 3B may be applied to the peripheral circuit region PERI. However, the peripheral circuit region PERI may not include bonding structure, for example, the first bonding vias 295, the first bonding pads 298, and the first bonding insulating layer 299, unlike the first semiconductor structure S1.

Unless otherwise described, the description of the second semiconductor structure S2 described above with reference to FIGS. 1 to 3B may be applied to the memory cell region CELL. However, unlike the second semiconductor structure S2, the memory cell region CELL may not include the bonding structure, i.e., the second bonding vias 195, the second bonding pads 198, and the second bonding insulating layer 199, and may also not include the passivation layer 106. The memory cell region CELL may further include first and second horizontal conductive layers 102 and 104 and a horizontal insulating structure 110 on the plate layer 101.

The first and second horizontal conductive layers 102 and 104 may be sequentially stacked and disposed on the upper surface of the plate layer 101. The first horizontal conductive layer 102 may function as a portion of a common source line of the semiconductor device 100e, and may function as a common source line, for example, together with the plate layer 101. The first horizontal conductive layer 102 may be directly connected to the channel layer of each of the channel structures CH around the channel layer. The first and second horizontal conductive layers 102 and 104 may include a semiconductor material, for example, may include polycrystalline silicon.

The horizontal insulating structure 110 may be disposed on the plate layer 101 in parallel with the first horizontal conductive layer 102. The horizontal insulating structure 110 may include three horizontal insulating layers sequentially stacked on the plate layer 101. The horizontal insulating structure 110 may include layers remaining after a portion thereof is replaced with the first horizontal conductive layer 102 during a manufacturing process of the semiconductor device 100e. The horizontal insulating structure 110 may include silicon oxide, silicon nitride, silicon carbide, or silicon oxynitride.

The substrate insulating layers 121 of this example implementation may be disposed to penetrate through the plate layer 101, the horizontal insulating structure 110, and the second horizontal conductive layer 104. Cell contact plugs 170e may penetrate through the gate electrodes 130 and may penetrate through the substrate insulating layer 121 and may thus be connected to the third circuit interconnection lines 268 of the peripheral circuit region PERI.

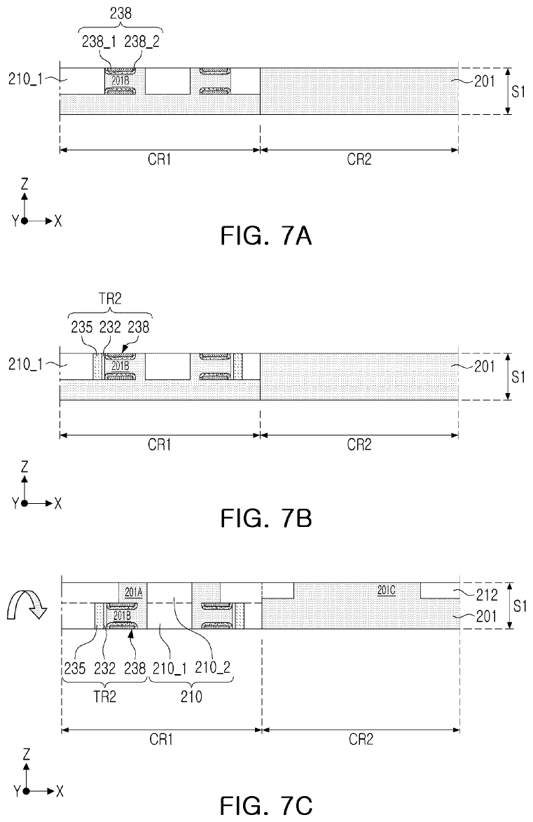

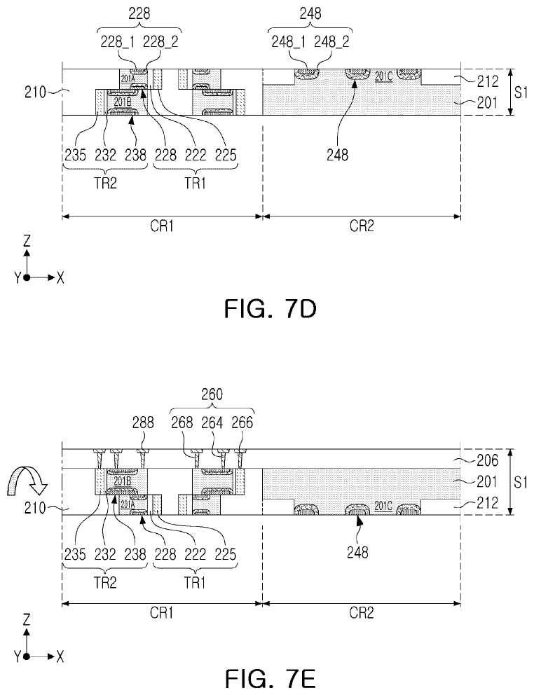

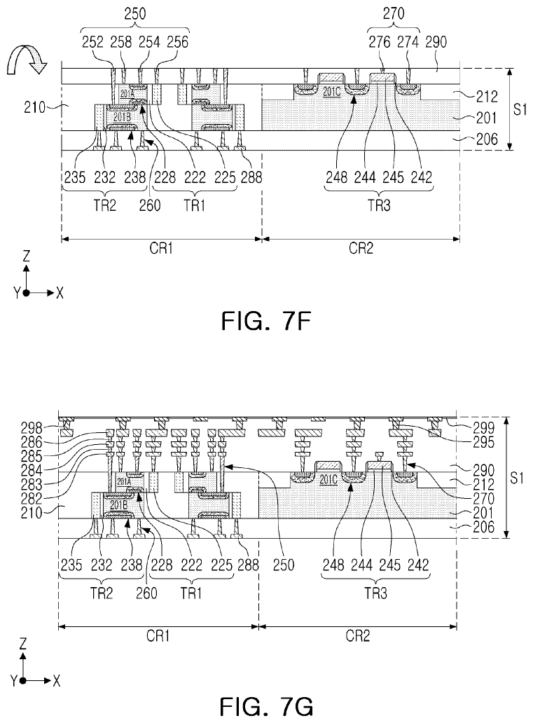

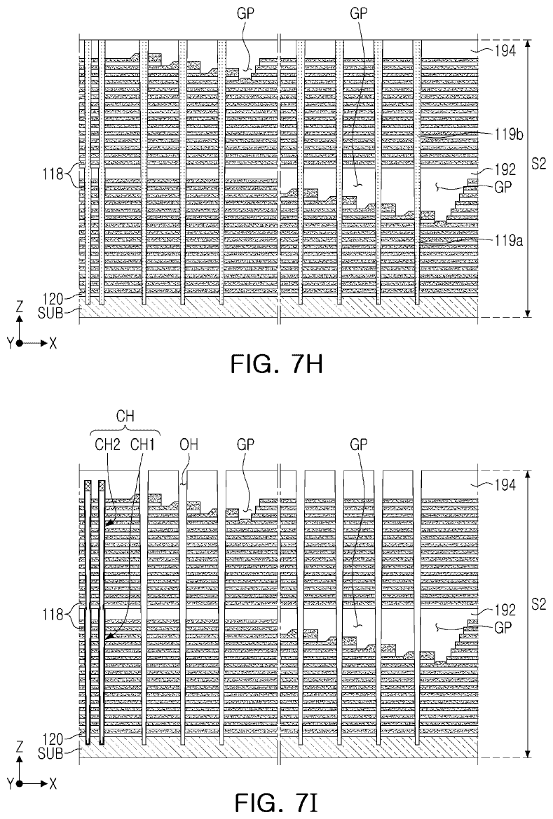

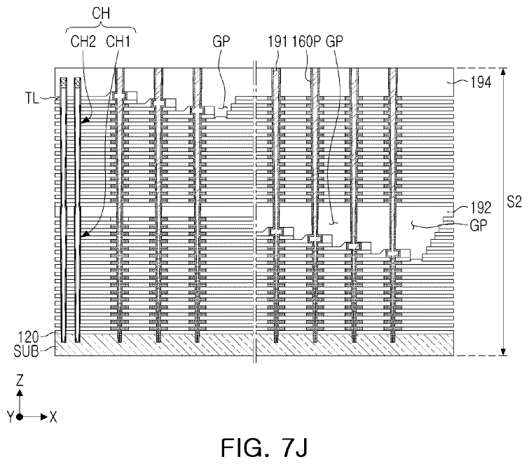

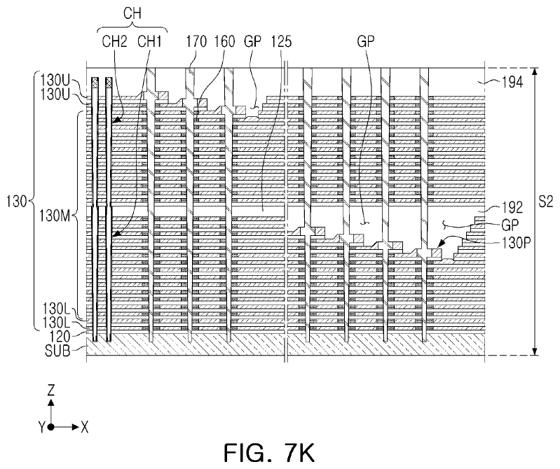

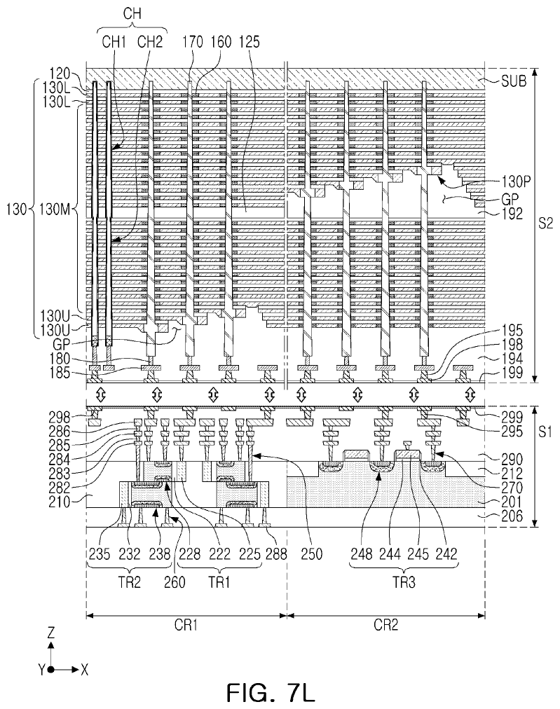

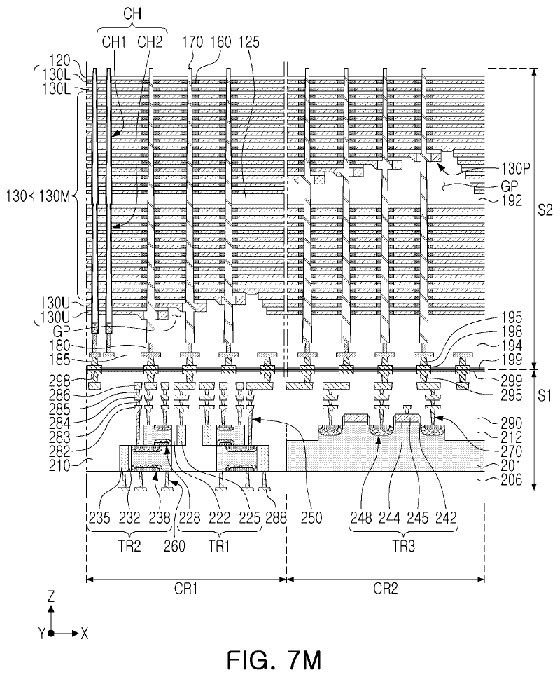

FIGS. 7A to 7M are schematic cross-sectional views illustrating a method of manufacturing a semiconductor device according to example implementations. FIGS. 7A to 7M illustrate regions corresponding to FIG. 1.

Referring to FIG. 7A, second semiconductor regions 201B may be defined in a substrate 201, and second source/drain regions 238 may be formed.

The substrate 201 may be a semiconductor substrate, for example, a thinned semiconductor wafer. The substrate 201 may be prepared by being removed and thinned by, for example, lapping, grinding, polishing, or an etching process. A thickness of the substrate 201 may be in a range of about 10 μm to about 50 μm, but is not limited thereto. In this operation, the substrate 201 may be prepared in a form in which the substrate 201 of FIG. 1 is inverted, that is, a lower surface of the substrate 201 of FIG. 1 becomes a upper surface thereof in FIG. 7A.

A first region 210_1 of the first element isolation layer 210 (see FIG. 1) may be formed in the substrate 201 to define second semiconductor regions 201B. The first region 210_1 may be formed at a predetermined depth from the upper surface of the substrate 201.

The second source/drain regions 238 may be formed at different depths in the second semiconductor regions 201B in an ion implantation process. Each of the second source/drain regions 238 may include first and second impurity regions 238_1 and 238_2 having different doping concentrations. Some of the second source/drain regions 238 may extend from upper surfaces of the second semiconductor regions 201B into the second semiconductor regions 201B, and others thereof may extend from lower surfaces of the second semiconductor regions 201B into the second semiconductor regions 201B. In some example implementations, others thereof may be formed in a region including the lower surfaces of the second semiconductor regions 201B.

Referring to FIG. 7B, second gate dielectric layers 232 and second gate electrode layers 235 may be formed.

The first regions 210_1 may be partially removed and a conductive material may be deposited to form the second gate electrode layers 235. Portions of the first regions 210_1 remaining between the second gate electrode layers 235 and the second semiconductor regions 201B may form the second gate dielectric layers 232. Alternatively, openings may be formed in the first regions 210_1, and insulating materials and conductive materials may be sequentially deposited thereinto, thus forming the second gate dielectric layers 232 and the second gate electrode layers 235 may be formed by. Accordingly, the second circuit elements TR2 may be formed.

Referring to FIG. 7C, first semiconductor regions 201A may be defined in the substrate 201.

The substrate 201 may be inverted to be formed in the same direction as the substrate 201 of FIG. 1. The first semiconductor regions 201A may be defined by forming a second region 210_2 of the first element isolation layer 210 in the substrate 201. The second region 210_2 may be formed at a predetermined depth from the upper surface of the substrate 201, and may be formed to be connected or in contact with the first region 210_1.

In this operation, the second element isolation layer 212 of the second circuit region CR2 may also be formed together to define the third semiconductor region 201C. However, in some example implementations, the second element isolation layer 212 may be formed in a subsequent process operation.

Referring to FIG. 7D, the first source/drain regions 228 may be formed, and the first gate dielectric layers 222 and the first gate electrode layers 225 may be formed.

The first source/drain regions 228 may be formed at different depths in the first semiconductor regions 201A in an ion implantation process. Each of the first source/drain regions 228 may include first and second impurity regions 228_1 and 228_2 having different doping concentrations. Some of the first source/drain regions 228 may extend from upper surfaces of the first semiconductor regions 201A into the first semiconductor regions 201A, and others thereof may extend from lower surfaces of the first semiconductor regions 201A or regions adjacent thereto into the first semiconductor regions 201A.

The first element isolation layer 210 may be partially removed from an upper surface thereof and a conductive material may be deposited therein to form the first gate electrode layers 225. Portions of the first element isolation layer 210 remaining between the first gate electrode layers 225 and the first semiconductor regions 201A may form the first gate dielectric layers 222. Alternatively, an opening may be formed in the first element isolation layer 210, and insulating materials and conductive materials may be sequentially deposited thereinto to form the first gate dielectric layers 222 and the first gate electrode layers 225. Accordingly, the first circuit elements TR1 may be formed.

In this operation, the third source/drain regions 248 of the second circuit region CR2 may also be formed together. Each of the third source/drain regions 248 may include first and second impurity regions 248_1 and 248_2 having different doping concentrations. However, in some example implementations, the third source/drain regions 248 may be formed separately in a subsequent process operation.

Referring to FIG. 7E, backside contacts 260 and backside interconnection lines 288 may be formed.

The substrate 201 may be inverted again, and the substrate 201 of FIG. 1 may be prepared in an inverted form. A backside insulating layer 206 may be formed on the upper surface of the substrate 201, and the backside insulating layer 206 may be partially removed and a conductive material may be filled in the removed portion, thus forming backside contacts 260. The backside contacts 260 may include a backside source/drain contact 264 connected to the second source/drain region 238 in an upper portion, a backside gate contact 266 connected to the second gate electrode layer 235, and a backside body contact 268 connected to the second semiconductor region 201B. Backside interconnection lines 288 may be formed on the backside contacts 260.

Referring to FIG. 7F, first front contacts 250 and second front contacts 270 may be formed.

The substrate 201 may be inverted to be formed in the same direction as the substrate 201 of FIG. 1. First, in the second circuit region CR2, third gate dielectric layers 242, third gate electrode layers 245, and gate spacers 244 may be formed on the upper surface of the substrate 201, thereby forming third circuit elements TR3.

A peripheral region insulating layer 290 may be partially formed on the first to third circuit elements TR1, TR2 and TR3, and the peripheral region insulating layer 290 may be partially removed and a conductive material may be filled in the removed portion, thus forming first front contacts 250 and second front contacts 270. The first front contacts 250 may include a first source/drain contact 254 connected to the first source/drain region 228, a first gate contact 256 connected to the first gate electrode layer 225, a first body contact 258 connected to the first semiconductor region 201A, and a common source/drain contact 252 connected to the second source/drain region 238 in an upper portion. The second front contacts 270 may include a third source/drain contact 274 connected to the third source/drain region 248 and a third gate contact 276 connected to the third gate electrode layer 245.

Referring to FIG. 7G, first and second circuit contact plugs 283 and 285 and first to third circuit interconnection lines 282, 284 and 286 may be formed, and a first bonding structure may be formed.

The first and second circuit contact plugs 283 and 285 may be formed by partially forming a peripheral region insulating layer 290, then partially etching and removing the peripheral region insulating layer 290, and filling the removed portion with a conductive material. The first to third circuit interconnection lines 282, 284 and 286 may be formed, for example, by depositing a conductive material thereon and then patterning the conductive material.

Next, a first bonding insulating layer 299 may be formed on the third circuit interconnection lines 268. The first bonding vias 295 and the first bonding pads 298 of the first bonding structure may be formed after partially removing the first bonding insulating layer 299 and the peripheral region insulating layer 290.

By this operation, the first substrate structure S1 may be prepared.

Referring to FIG. 7H, a manufacturing process of the second substrate structure S2 may be started. First, sacrificial insulating layers 118 and interlayer insulating layers 120 may be alternately stacked on a base substrate SUB, and then first and second vertical sacrificial layers 119a and 119b may be formed.

The base substrate SUB is a layer removed through a subsequent process and may be a semiconductor substrate such as undoped silicon (Si).

The sacrificial insulating layers 118 and interlayer insulating layers 120 may be alternately stacked to form a lower mold structure. The lower mold structure may be formed at a height at which the first channel structures CH1 (see FIG. 1) are disposed. Next, the sacrificial insulating layers 118 and the interlayer insulating layers 120 may be partially removed from an upper portion to form staircase regions GP. The sacrificial insulating layers 118 may form a staircase-shaped step structure in predetermined units, and sacrificial insulating layers 118 disposed in an uppermost portion of the sacrificial insulating layers 118 in the staircase regions GP may be exposed upwardly. The sacrificial insulating layers 118 disposed at the uppermost portion thereof may have an increased thickness in ends thereof.

A first cell region insulating layer 192 covering the lower mold structure may be formed, and first vertical sacrificial layers 119a penetrating through the lower mold structure may be formed. The first vertical sacrificial layers 119a may be formed in positions corresponding to the first channel structures CH1 and cell contact plugs 170 of FIG. 1. The first vertical sacrificial layers 119a may include, for example, polycrystalline silicon, a carbon-based material, or a metallic material.

An upper mold structure may be formed on the lower mold structure in the same manner, and second vertical sacrificial layers 119b may be formed. The second vertical sacrificial layers 119b may be formed to be connected to the first vertical sacrificial layers 119a, respectively. Although not specifically illustrated, a step structure may also be formed between the first and second vertical sacrificial layers 119a and 119b formed in positions corresponding to the cell contact plugs 170.

Referring to FIG. 7I, channel structures CH and cell contact holes OH may be formed.

The channel structures CH may be formed by removing some of the first and second vertical sacrificial layers 119a and 119b to form hole-shaped channel holes, and then depositing a channel layer, a channel dielectric layer, and the like. The cell contact holes OH may be formed by removing other some of the first and second vertical sacrificial layers 119a and 119b.

Referring to FIG. 7J, preliminary contact insulating layers 160P and vertical sacrificial layers 191 may be formed in the cell contact holes OH, and the sacrificial insulating layers 118 may be removed.

Portions of the sacrificial insulating layers 118 exposed through the cell contact holes OH may be removed. The sacrificial insulating layers 118 may be removed by a predetermined length around the cell contact holes OH, thus forming tunnel portions. In one staircase region GP, the tunnel portions may be formed to have a relatively short length in the sacrificial insulating layer 118 in an uppermost portion, and may be formed to have a relatively long length in the sacrificial insulating layers 118 therebelow.

An insulating material may be deposited in the cell contact holes OH and the tunnel portions, thus forming the preliminary contact insulating layers 160P. The preliminary contact insulating layers 160P may be formed on sidewalls of the cell contact holes OH and may fill the tunnel portions. The preliminary contact insulating layers 160P may not completely fill tunnel portions in an uppermost portion of the staircase regions GP. The vertical sacrificial layers 191 may fill the cell contact holes OH and the tunnel portions in the uppermost portion. The vertical sacrificial layers 191 may include a different material from the preliminary contact insulating layers 160P, and may include, for example, polycrystalline silicon.

In a region not illustrated, openings extending to the base substrate SUB by penetrating through the sacrificial insulating layers 118 and the interlayer insulating layers 120 may be formed. The sacrificial insulating layers 118 may be removed through the openings. The sacrificial insulating layers 118 may be selectively removed with respect to the interlayer insulating layers 120, the preliminary contact insulating layers 160P, and the like, for example, using wet etching. Accordingly, tunnel portions TL may be formed in regions from which the sacrificial insulating layers 118 are removed.

Referring to FIG. 7K, gate electrodes 130 and cell contact plugs 170 may be formed.

The gate electrodes 130 may be formed by depositing a conductive material on the tunnel portions TL. The conductive material may include a metal, polycrystalline silicon, or a metal silicide material.

The vertical sacrificial layers 191 in the cell contact holes OH may be removed. The vertical sacrificial layers 191 may be selectively removed with respect to the interlayer insulating layers 120 and the gate electrodes 130. Portions of the exposed preliminary contact insulating layers 160P after the vertical sacrificial layers 191 are removed may also be removed. In this case, the preliminary contact insulating layers 160P may be completely removed in the pad regions 130P, and may remain therebelow to form the contact insulating layers 160.

The cell contact plugs 170 may be formed by depositing a conductive material in the cell contact holes OH. The cell contact plugs 170 may be formed to have horizontal extension portions expanded horizontally in the pad regions 130P, and thereby may be physically and electrically connected to the gate electrodes 130.

Referring to FIG. 7l, a second interconnection structure and a second bonding structure may be formed on the gate electrodes 130, and the first substrate structure S1 and the second substrate structure S2 may be bonded to each other.

Among the second interconnection structures, the studs 180 may be formed by etching cell region insulating layer 190 on lower surfaces of the channel structures CH and the cell contact plugs 170 and depositing a conductive material thereon. The cell interconnection lines 185 may be formed through a deposition and patterning process of a conductive material, or by partially forming the cell region insulating layer 190 and then patterning the cell region insulating layer 190 and depositing a conductive material thereon.

Among the second bonding structures, the second bonding insulating layer 199 may be formed on a lower surface of the cell region insulating layer 190. Next, the second bonding insulating layer 199 and the cell region insulating layer 190 may be partially removed and a conductive material may be deposited in the removed portion to form second bonding vias 195, and then, the second bonding pads 198 may be formed on the second bonding vias 195. In some example implementations, the second bonding vias 195 and the second bonding pads 198 disposed vertically may be formed integrally with each other. Lower surfaces of the second bonding pads 198 may be exposed from the cell region insulating layer 190.

Next, the first substrate structure S1 and the second substrate structure S2 may be connected to each other by bonding the first bonding pads 298 and the second bonding pads 198 by annealing and/or applying pressure. At the same time, the first bonding insulating layer 299 and the second bonding insulating layer 199 may also be bonded. The second substrate structure S2 may be flipped over on the first substrate structure S1 to allow the second bonding pads 198 to face downwardly, and then bonding may be performed. The first substrate structure S1 and the second substrate structure S2 may be directly bonded to each other without the intervention of an adhesive such as a separate adhesive layer.

Referring to FIG. 7M, the base substrate SUB may be removed from the bonding structure of the first and second substrate structures S1 and S2.

For example, a portion of the base substrate SUB may be removed from an upper surface in a polishing process such as a grinding process, and the remainder may be removed in an etching process such as wet etching. As the base substrate SUB is removed, upper ends of the channel structures CH and the cell contact plugs 170 may be exposed. The channel dielectric layers may be partially removed from the upper ends of the exposed channel structures CH so that the channel layer may be exposed.

Next, referring to FIG. 1 together, a semiconductor material may be deposited on the upper ends of the channel structures CH to form a plate layer 101, and an insulating material may be deposited on the upper ends of the cell contact plugs 170 to form a substrate insulating layer 121. The plate layer 101 may be formed, for example, by depositing amorphous silicon (Si) and then crystallizing the same. A passivation layer 106 may be formed on the plate layer 101.

Accordingly, the semiconductor device 100 of FIG. 1 may be manufactured.

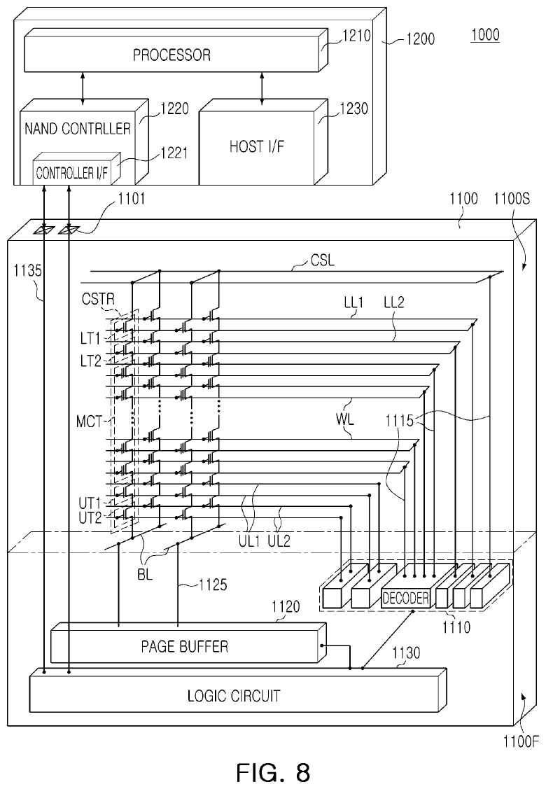

FIG. 8 is a schematic view of a data storage system including a semiconductor device according to example implementations.

Referring to FIG. 8, a data storage system 1000 may include a semiconductor device 1100 and a controller 1200 electrically connected to the semiconductor device 1100. The data storage system 1000 may be a storage device including one or a plurality of semiconductor devices 1100 or an electronic device including the storage device. For example, the data storage system 1000 may be a solid state drive device (SSD), a Universal Serial Bus (USB), a computing system, a medical device, or a communication device, including one or a plurality of semiconductor devices 1100.

The semiconductor device 1100 may be a nonvolatile memory device, and may be, for example, a NAND flash memory device described above with reference to FIGS. 1 to 6. The semiconductor device 1100 may include a first structure 1100F and a second structure 1100S on the first structure 1100F. In example implementations, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously changed according to example implementations.

In example implementations, the upper transistors UT1 and UT2 may include string select transistors, and the lower transistors LT1 and LT2 may include ground select transistors. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In example implementations, the lower transistors LT1 and LT2 may include a lower erase control transistor LT1 and a ground select transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used for an erase operation of erasing data stored in the memory cell transistors MCT by utilizing a GIDL phenomenon.

The common source line CSL, the first and second gate lower lines LL1 and LL2, the word lines WL, and the first and second gate upper lines UL1 and UL2 may be electrically connected to the decoder circuit 1110 through first interconnection lines 1115 extending from the first structure 1100F to the second structure 1100S. The bit lines BL may be electrically connected to the page buffer 1120 through second connection interconnection lines 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output interconnection line 1135 that extending from the first structure 1100F to the second structure 1100S.

The controller 1200 may include a processor 1210, a NAND controller 1220, and a host interface 1230. According to example implementations, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may control the NAND controller 1220 to access the semiconductor device 1100. The NAND controller 1220 may include a NAND interface 1221 processing communication with the semiconductor device 1100. Through the NAND interface 1221, a control command for controlling the semiconductor device 1100, data to be recorded in the memory cell transistors MCT of the semiconductor device 1100, data to be read from the memory cell transistors MCT of the semiconductor device 1100, or the like, may be transmitted. The host interface 1230 may provide a communication function between the data storage system 1000 and an external host. When the control command is received from the external host through the host interface 1230, the processor 1210 may control the semiconductor device 1100 in response to the control command.

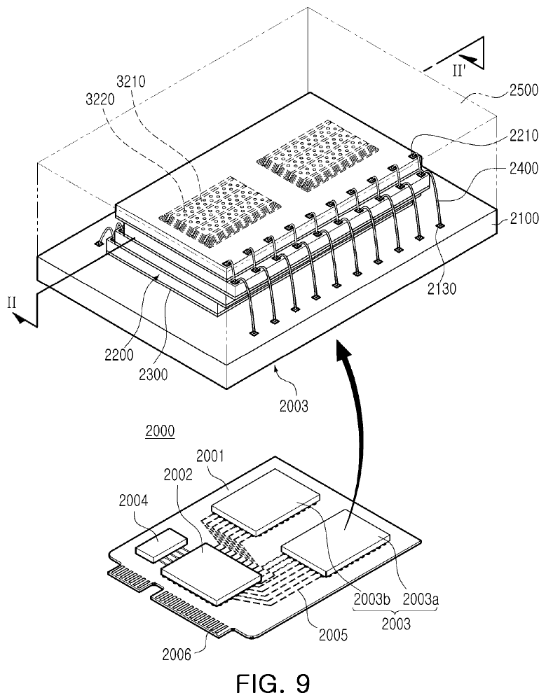

FIG. 9 is a perspective view schematically illustrating a data storage system including a semiconductor device according to example implementations.

Referring to FIG. 9, a data storage system 2000 according to an example implementation of the present disclosure may include a main substrate 2001, a controller 2002 mounted on the main substrate 2001, one or more semiconductor packages 2003, and a DRAM 2004. The semiconductor package 2003 and the DRAM 2004 may be connected to the controller 2002 by interconnection patterns 2005 formed on the main substrate 2001.

The main substrate 2001 may include a connector 2006 including a plurality of pins coupled to the external host. The number and arrangement of the plurality of pins in the connector 2006 may vary depending on a communication interface between the data storage system 2000 and the external host. In example implementations, the data storage system 2000 may communicate with the external host according to any one of interfaces such as Universal Serial Bus (USB), Peripheral Component Interconnect Express (PCI-Express), Serial Advanced Technology Attachment (SATA), and M-Phy for Universal Flash Storage (UFS). In example implementations, the data storage system 2000 may operate by power supplied from the external host through the connector 2006. The data storage system 2000 may further include a Power Management Integrated Circuit (PMIC) distributing the power supplied from the external host to the controller 2002 and the semiconductor package 2003.

The controller 2002 may record data in the semiconductor package 2003 or read data from the semiconductor package 2003, and may improve the operating speed of the data storage system 2000.

The DRAM 2004 may be a buffer memory for mitigating a speed difference between the semiconductor package 2003, which is a data storage space, and the external host. The DRAM 2004 included in the data storage system 2000 may also function as a kind of cache memory, and may provide a space for temporarily storing data in a control operation for the semiconductor package 2003. When the DRAM 2004 is included in the data storage system 2000, the controller 2002 may further include a DRAM controller for controlling DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of each of the semiconductor chips 2200, a connection structure 2400 electrically connecting the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to an input/output pad 1101 of FIG. 8. Each of the semiconductor chips 2200 may include gate stack structures 3210 and channel structures 3220. Each of the semiconductor chips 2200 may include the semiconductor device described above with reference to FIGS. 1 to 6.

In example implementations, the connection structure 2400 may be a bonding wire for electrically connecting the input/output pad 2210 and the package upper pads 2130. Accordingly, in each of the first and second semiconductor packages 2003a and 2003b, the semiconductor chips 2200 may be electrically connected to each other in a bonding wire manner and may be electrically connected to the package upper pads 2130 of the package substrate 2100. According to example implementations, in each of the first and second semiconductor packages 2003a and 2003b, the semiconductor chips 2200 may be electrically connected to each other by a connecting structure including a through-silicon via (TSV), instead of a connecting structure 2400 in a bonding wire manner.

In example implementations, the controller 2002 and the semiconductor chips 2200 may be included in one package. In an example implementation, the controller 2002 and the semiconductor chips 2200 may be mounted on a separate interposer substrate different from a main substrate 2001, and the controller 2002 and the semiconductor chips 2200 may be connected to each other by interconnection lines formed on the interposer substrate.

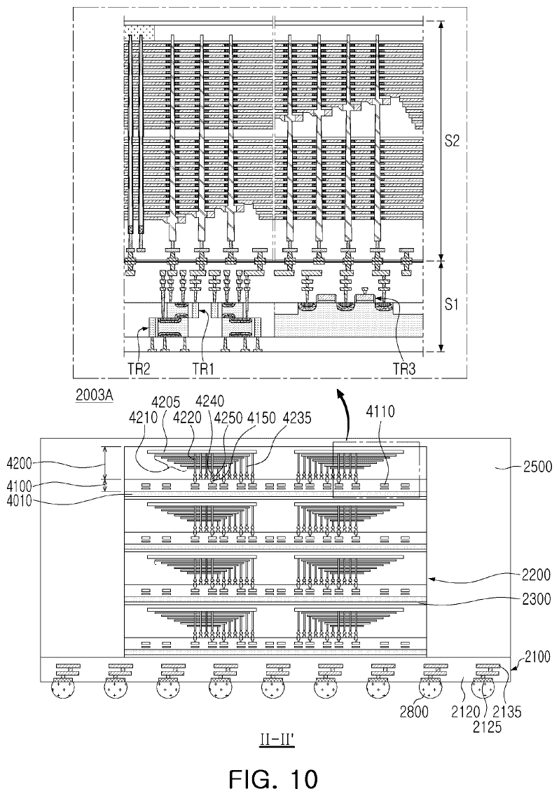

FIG. 10 is a schematic cross-sectional view of a semiconductor package according to example implementations. FIG. 10 describes an example implementation of a semiconductor package 2003 of FIG. 9, and conceptually illustrates a region cut along line II-II′ of the semiconductor package 2003 of FIG. 9.

Referring to FIG. 10, in a semiconductor package 2003A, the package substrate 2100 may be a printed circuit board. The package substrate 2100 may include a package substrate body 2120, lower pads 2125 disposed on a lower surface of the package substrate body 2120 or exposed through the lower surface thereof, and internal interconnection lines 2135 electrically connecting the upper pads 2130 and the lower pads 2125 in the package substrate body 2120. The lower pads 2125 may be connected to the interconnection patterns 2005 of the main substrate 2001 of the electronic system 2000 through conductive connecting portions 2800, as illustrated in FIG. 9.

Each of the semiconductor chips 2200 may include a semiconductor substrate 4010, a first structure 4100 on the semiconductor substrate 4010, and a second structure 4200 bonded to the first structure 4100 in a wafer bonding manner on the first structure 4100.

The first structure 4100 may include a peripheral circuit region including peripheral interconnection lines 4110 and first bonding structures 4150. The second structure 4200 may include a common source line 4205, a gate stack structure 4210 between the common source line 4205 and the first structure 4100, channel structures 4220 penetrating through the gate stack structure 4210, and second bonding structures 4250 electrically connected to the memory channel structures 4220 and word lines (WL in FIG. 8) of the gate stack structure 4210, respectively. For example, the second bonding structures 4250 may be electrically connected to the memory channel structures 4220 and the word lines, respectively, through bit lines 4240 electrically connected to the memory channel structures 4220 and cell contact plugs 4235 electrically connected to the word lines. The first bonding structures 4150 of the first structure 4100 and the second bonding structures 4250 of the second structure 4200 may be bonded while contacting each other. The bonded portions of the first bonding structures 4150 and the second bonding structures 4250 may be formed of, for example, copper (Cu).

In each of the semiconductor chips 2200, as illustrated in the enlarged view, the first structures 4100 and S1 may include a VTFET, and may include vertically aligned first and second circuit elements TR1 and TR2 and third circuit elements TR3 including a planar transistor. Each of the semiconductor chips 2200 may further include an input/output pad 2210 (see FIG. 9) electrically connected to the peripheral interconnection lines 4110 of the first structure 4100.

The semiconductor chips 2200 may be electrically connected to each other by connection structures 2400 (see FIG. 9) in the form of bonding wires. However, in example implementations, the semiconductor chips in a single semiconductor package, such as the semiconductor chips 2200, may also be electrically connected to each other by connection structures including through-silicate vias (TSV).

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device, comprising:
a first substrate structure including
a substrate,
a first circuit element and a second circuit element sequentially arranged in the substrate in a first direction perpendicular to an upper surface of the substrate,
a first interconnection structure on the substrate, and
first bonding pads on the first interconnection structure; and
a second substrate structure on the first substrate structure, the second substrate structure including
a plate layer,
gate electrodes spaced apart from each other and stacked in the first direction below the plate layer,
channel structures extending into the gate electrodes in the first direction,
a second interconnection structure below the gate electrodes, and
second bonding pads below the second interconnection structure and connected to the first bonding pads,
wherein the substrate includes a first semiconductor region extending from the upper surface of the substrate into the substrate in the first direction, and a second semiconductor region extending from a lower surface of the substrate into the substrate in the first direction and contacting the first semiconductor region,
wherein the first circuit element includes a first gate dielectric layer on a side surface of the first semiconductor region, a first gate electrode layer on the first gate dielectric layer, and first source/drain regions respectively in an upper portion and a lower portion of the first semiconductor region,
wherein the second circuit element includes a second gate dielectric layer on a side surface of the second semiconductor region, a second gate electrode layer on the second gate dielectric layer, and second source/drain regions respectively in an upper portion and a lower portion of the second semiconductor region, and
wherein in a second direction perpendicular to the first direction, the first semiconductor region has a first width, and the second semiconductor region has a second width greater than the first width.

2. The semiconductor device of claim 1,
wherein each of the first and second semiconductor regions has first and second side surfaces extending in the first direction and arranged in the second direction, the first side surface of the first semiconductor region is the side surface of the first semiconductor region, the second side surface of the second semiconductor region is the side surface of the second semiconductor region, the first side surfaces are on a same corresponding side of first and second semiconductor regions, respectively, and
the first gate electrode layer is on the first side surface of the first semiconductor region, and the second gate electrode layer is on the second side surface of the second semiconductor region.

3. The semiconductor device of claim 1,
wherein the first source/drain regions comprise a first upper region and a first lower region, the first upper region is in the upper portion of the first semiconductor region, and the first lower region is in the lower portion of the first semiconductor region,
wherein the second source/drain regions comprise a second upper region and a second lower region, the second upper region is in the upper portion of the second semiconductor region, and the second lower region is in the lower portion of the second semiconductor region,
the first lower region of the first source/drain regions is in contact with the second upper region of the second source/drain regions.

4. The semiconductor device of claim 3,
wherein the first substrate structure includes:
an element isolation layer defining the first semiconductor region and the second semiconductor region in the substrate; and
a common source/drain contact extending into the element isolation layer and connected to the second upper region of the second source/drain regions, the common source/drain contact electrically connected to the first lower region of the first source/drain regions through the second upper region of the second source/drain regions.

5. The semiconductor device of claim 1,
wherein the second source/drain regions comprise a second upper region and a second lower region, the second upper region is in the upper portion of the second semiconductor region, and the second lower region is in the lower portion of the second semiconductor region, and
wherein the first substrate structure includes:
a backside insulating layer on the lower surface of the substrate; and
a backside source/drain contact extending into the backside insulating layer and connected to the second lower region of the second source/drain regions.

6. The semiconductor device of claim 5,
wherein the first substrate structure includes:
a backside body contact extending into the backside insulating layer and connected to the second semiconductor region; and
a backside gate contact extending into the backside insulating layer and connected to the second gate electrode layer.

7. The semiconductor device of claim 1,
wherein an upper surface of the first gate electrode layer is coplanar with the upper surface of the substrate, and a lower surface of the second gate electrode layer is coplanar with the lower surface of the substrate.

8. The semiconductor device of claim 7,
wherein an upper surface of the first gate dielectric layer is coplanar with the upper surface of the substrate.

9. The semiconductor device of claim 1,
wherein the first source/drain regions comprise a first upper region and a first lower region, the first upper region is in the upper portion of the first semiconductor region, and the first lower region is in the lower portion of the first semiconductor region,
wherein the second source/drain regions comprise a second upper region and a second lower region, the second upper region is in the upper portion of the second semiconductor region, and the second lower region is in the lower portion of the second semiconductor region,
wherein an upper surface of the first upper region of the first source/drain regions is coplanar with the upper surface of the substrate, and
wherein a lower surface of the second lower region of the second source/drain regions is coplanar with the lower surface of the substrate.

10. The semiconductor device of claim 1,
wherein the first gate dielectric layer has a first width in the second direction, and the second gate dielectric layer has a second width different from the first width in the second direction.

11. The semiconductor device of claim 10,
wherein the first width is greater than the second width, and
the first gate electrode layer has a first length in the first direction, and the second gate electrode layer has a second length greater than the first length in the first direction.

12. The semiconductor device of claim 1,
wherein the first circuit element and the second circuit element have different threshold voltages.

13. The semiconductor device of claim 1,
wherein the first substrate structure includes a third circuit element on a side of the second circuit element in the substrate.

14. A semiconductor device, comprising:
a first substrate structure including
a substrate,
a first circuit element and a second circuit element sequentially arranged in the substrate in a first direction perpendicular to an upper surface of the substrate, and
an element isolation layer in the substrate; and
a second substrate structure on the first substrate structure, the second substrate structure including
a plate layer,
gate electrodes spaced apart from each other and stacked in the first direction on a surface of the plate layer, and
channel structures extending into the gate electrodes in the first direction,
wherein the substrate includes a first semiconductor region extending into the substrate from the upper surface of the substrate in the first direction and a second semiconductor region extending into the substrate from a lower surface of the substrate in the first direction,
wherein the first circuit element includes a first gate electrode layer on a side surface of the first semiconductor region, and first source/drain regions respectively in an upper portion and a lower portion of the first semiconductor region,
wherein the second circuit element includes a second gate electrode layer on a side surface of the second semiconductor region, and second source/drain regions respectively in an upper portion and a lower portion of the second semiconductor region, and
wherein a first portion of an upper surface of the second semiconductor region is in contact with the first semiconductor region, and a second portion of the upper surface of the second semiconductor region is in contact with the element isolation layer.

15. The semiconductor device of claim 14,
wherein the first substrate structure includes a common source/drain contact connected to the second portion of the upper surface of the second semiconductor region by extending into a portion of the element isolation layer from the upper surface of the substrate.

16. The semiconductor device of claim 14,
wherein the first source/drain regions comprise a first upper region and a first lower region, the first upper region is in the upper portion of the first semiconductor region, and the first lower region is in the lower portion of the first semiconductor region,
wherein the second source/drain regions comprise a second upper region and a second lower region, the second upper region is in the upper portion of the second semiconductor region, and the second lower region is in the lower portion of the second semiconductor region, and
wherein the first lower region of the first source/drain regions is electrically connected to the second upper region of the second source/drain regions.

17. The semiconductor device of claim 14,
wherein the substrate includes a third semiconductor region spaced apart from the first and second semiconductor regions, and
wherein the first substrate structure includes a third circuit element, the third circuit element including a third gate electrode layer on the third semiconductor region and third source/drain regions in the third semiconductor region on both sides of the third gate electrode layer, respectively.

18. The semiconductor device of claim 17,
wherein the first gate electrode layer has a first length in the first direction,
wherein the second gate electrode layer has a second length different from the first length in the first direction, and
wherein the third gate electrode layer has a third length less than at least one of the first length or the second length, the third length being in a second direction perpendicular to the first direction.

19. A data storage system, comprising:
a semiconductor storage device including (i) a first substrate structure including a substrate, a first circuit element, and a second circuit element, (ii) a second substrate structure including gate electrodes, and (iii) an input/output pad electrically connected to the first and second circuit elements; and
a controller electrically connected to the semiconductor storage device through the input/output pad and configured to control the semiconductor storage device,
wherein the first circuit element and the second circuit element are stacked in the substrate in a first direction perpendicular to an upper surface of the substrate, and
wherein the first substrate structure includes
a peripheral region insulating layer on the upper surface of the substrate,
a backside insulating layer on a lower surface of the substrate,
front contacts electrically connected to the first circuit element by extending into the peripheral region insulating layer,
backside contacts electrically connected to the second circuit element by extending into the backside insulating layer, and
a common contact electrically connected to the first circuit element and the second circuit element by extending into the peripheral region insulating layer.

20. The data storage system of claim 19,
wherein a channel direction of the first circuit element and the second circuit element is the first direction.
